(19) United States
(12) Patent Application Publication
(10) Pub. No.: US 2026/0101563 A1
(43) Pub. Date: Apr. 9, 2026

(54) SEMICONDUCTOR DEVICE AND METHOD OF MANUFACTURING THE SAME

(71) Applicant: Renesas Electronics Corporation, Tokyo (JP)

(72) Inventors: Hideki OSADA, Tokyo (JP); Tadashi YAMAGUCHI, Tokyo (JP)

(21) Appl. No.: 19/349,141

(22) Filed: Oct. 3, 2025

(30) Foreign Application Priority Data
Oct. 4, 2024 (JP) 2024-174941

(51) Int. Cl. H10D 64/62; H10D 12/00; H10D 62/10; H10D 64/01; H10D 64/23

(52) U.S. Cl. CPC H10D 64/62; H10D 12/481; H10D 62/112; H10D 64/01; H10D 64/232

(57) ABSTRACT

A semiconductor device includes an insulating film, a metal film, and an adhesion intermediate film arranged between the insulating film and the metal film, and the adhesion intermediate film includes a first adhesion layer, a stress control layer, a second adhesion layer, and a barrier metal layer, which are mutually different and are arranged sequentially in a direction from the insulating film toward the metal film. The insulating film may contain silicon oxide.

### CROSS-REFERENCE TO RELATED APPLICATION

The disclosure of Japanese Patent Application No. 2024-174941 filed on Oct. 4, 2024, including the specification, drawings and abstract is incorporated herein by reference in its entirety.

### BACKGROUND

The present disclosure relates to a semiconductor device and a method of manufacturing the same.

There are disclosed techniques listed below.
[Patent Document 1] Japanese Unexamined Patent Application Publication No. 2024-003808
[Patent Document 2] Japanese Unexamined Patent Application Publication No. 2019-029434

The Patent Documents 1 and 2 describe that a wiring is formed on an interlayer insulating film in a semiconductor device.

### SUMMARY

It is desired to suppress peeling of the wiring formed on the interlayer insulating film.

Other problems and novel characteristics will become apparent from the description of the present specification and the accompanying drawings.

According to one embodiment, a semiconductor device includes an insulating film, a metal film, and an adhesion intermediate film arranged between the insulating film and the metal film. The adhesion intermediate film includes a first adhesion layer, a stress control layer, a second adhesion layer, and a barrier metal layer which are mutually different and are arranged sequentially in a direction from the insulating film toward the metal film.

According to one embodiment, a method of manufacturing a semiconductor device includes a step of forming an insulating film, a step of forming an adhesion intermediate film on the insulating film, and a step of forming a metal film on the adhesion intermediate film. The step of forming the adhesion intermediate film is to form the adhesion intermediate film including a first adhesion layer, a stress control layer, a second adhesion layer, and a barrier metal layer which are mutually different and are arranged sequentially in a direction from the insulating film toward the metal film.

According to one embodiment, peeling of a wiring formed on the interlayer insulating film can be suppressed.

### BRIEF DESCRIPTIONS OF THE DRAWINGS

FIG. 1 is a cross-sectional view illustrating a semiconductor device according to a comparative example.

FIG. 2 is a flowchart illustrating a method of manufacturing the semiconductor device according to the comparative example.

FIG. 3 is a flowchart illustrating another method of manufacturing the semiconductor device according to the comparative example.

FIG. 4 is a cross-sectional view illustrating a semiconductor device according to a first embodiment.

FIG. 5 is a cross-sectional view illustrating another semiconductor device according to the first embodiment.

FIG. 6 is a flowchart illustrating a method of manufacturing the semiconductor device according to the first embodiment.

FIG. 7 is a flowchart illustrating steps of manufacturing an adhesion intermediate film in the method of manufacturing the semiconductor device according to the first embodiment.

FIG. 8 is a diagram illustrating steps of manufacturing the adhesion intermediate film in the method of manufacturing the semiconductor device according to the first embodiment.

FIG. 9 is a flowchart illustrating a method of manufacturing a semiconductor device according to another example of the first embodiment.

FIG. 10 is a flowchart illustrating steps of manufacturing the adhesion intermediate film in a method of manufacturing a semiconductor device according to a first modification example of the first embodiment.

FIG. 11 is a diagram illustrating steps of manufacturing the adhesion intermediate film in the method of manufacturing the semiconductor device according to the first modification example of the first embodiment.

FIG. 12 is a diagram illustrating steps of manufacturing the adhesion intermediate film in a method of manufacturing a semiconductor device according to a second modification example of the first embodiment.

FIG. 13 is a diagram illustrating steps of manufacturing the adhesion intermediate film in a method of manufacturing a semiconductor device according to a second embodiment.

FIG. 14 is a cross-sectional view illustrating a semiconductor device according to a third embodiment.

### DETAILED DESCRIPTION

The following description and drawings may be appropriately omitted and simplified in order to make the explanation clear. Note that the same components are denoted by the same reference symbols throughout each drawing, and the repetitive description thereof is omitted if needed. Some reference symbols may be omitted in order to simply illustrate the drawings.

First, a method of manufacturing a semiconductor device according to a comparative example will be described in a chapter <Comparative Example>. Then, problems of the method of manufacturing the semiconductor device according to the comparative example, which have been found by the present inventors, will be described in a chapter <Problems found by Present Inventors>. Then, semiconductor devices and methods of manufacturing the semiconductor devices according to first to third embodiments will be described in chapters <First Embodiment> to <Third Embodiment> in comparison with the comparative example. Thereby, the semiconductor devices and the method of manufacturing the same according to the present embodiments will be made clearer. Note that the comparative example and the problems found by the present inventors are also within the scope of the technical idea of the embodiments.

### COMPARATIVE EXAMPLE

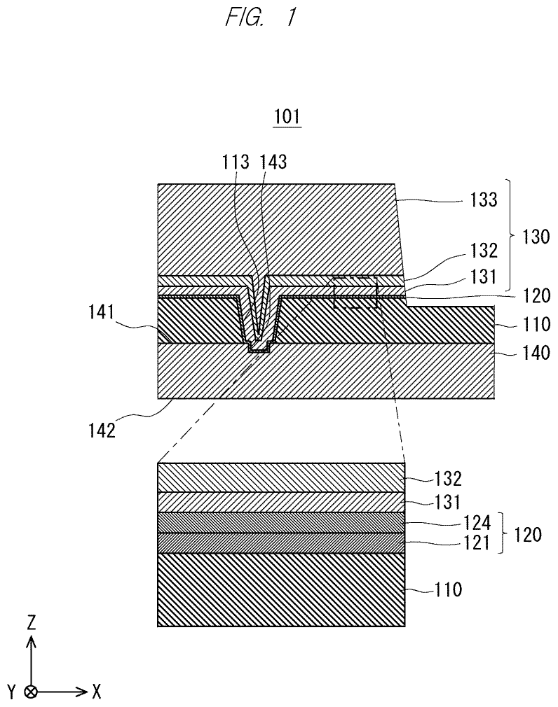

FIG. 1 is a cross-sectional view illustrating a semiconductor device 101 according to the comparative example. FIG. 1 also illustrates an enlarged drawing of a part of the semiconductor device 101. As illustrated in FIG. 1, the semiconductor device 101 includes an insulating film 110, an adhesion intermediate film 120, a metal film 130, and a semiconductor substrate 140.

The semiconductor substrate 140 has, for example, a plate shape. The plate shape of the semiconductor substrate 140 includes a first main surface 141 and a second main surface 142 opposite to the first main surface 141. An XYZ-Orthogonal coordinate system is introduced here for the convenience of describing the semiconductor device 101. A direction orthogonal to the first main surface 141 is assumed as Z-axis direction. A direction extending from the second main surface 142 toward the first main surface 141 is assumed as +Z-axis direction. The +Z-axis direction is referred to as upper side, and a −Z-axis direction is referred to as lower side. Note that the upper side and the lower side are used for the convenience of describing the semiconductor device 101, and do not indicate directions of arrangement of a practical semiconductor device 1.

A material of the semiconductor substrate 140 includes, for example, silicon (Si). Note that germanium (Ge), carbon (C), silicon carbide (SiC), gallium nitride (GaN) and others other than silicon are not excluded from the material of the semiconductor substrate 140.

A semiconductor element including a semiconductor layer may be formed in the semiconductor substrate 140. The semiconductor substrate 140 may include a contact hole 143 reaching the semiconductor layer of the semiconductor element. The semiconductor element includes, for example, an insulated gate bipolar transistor (IGBT). Note that the semiconductor element may be a metal oxide semiconductor field effect transistor (MOSFET) or a diode.

The insulating film 110 is formed on the first main surface 141 of the semiconductor substrate 140. A material of the insulating film 110 includes, for example, silicon oxide (SiO₂). Thus, a chemical element of the insulating film 110 includes silicon and oxygen (O). Note that a phosphorous silicate glass (PSG) film, a non-doped silicate glass (NSG) film, a spin-on-glass (SOG) film, a boron phosphor silicate glass (BPSG) film, or a composite film thereof and others other than silicon oxide are not excluded from the insulating film 110. The insulating film 110 may be formed by thermal oxidization of the semiconductor substrate 140. As the insulating film 110, at least either the material contained in the insulating film 110 or the material including the chemical element contained in the insulating film 110 may be formed on the semiconductor substrate 140 by performing a chemical vapor deposition (CVD) method. The insulating film 110 may include a contact hole 113 communicating with the contact hole 143. The adhesion intermediate film 120 is formed on the insulating film 110.

The adhesion intermediate film 120 is formed on the insulating film 110. The adhesion intermediate film 120 is arranged between the insulating film 110 and the metal film 130. The adhesion intermediate film 120 includes an adhesion layer 121 and a barrier metal layer 124. The adhesion intermediate film 120 includes an adhesion layer 121 and a barrier metal layer 124 which are different from each other and are arranged sequentially in a direction from the insulating film 110 toward the metal film 130.

The adhesion layer 121 is formed on the insulating film 110. A material of the adhesion layer 121 includes, for example, titanium (Ti). Thus, a chemical element of the adhesion layer 121 includes titanium. As the adhesion layer 121, at least either the material contained in the adhesion layer 121 or the material including the chemical element contained in the adhesion layer 121 may be formed on the insulating film 110 by performing a physical vapor deposition (PVD) method. The adhesion layer 121 may be formed on the inner walls of the contact hole 113 and the contact hole 143.

The barrier metal layer 124 is formed on the adhesion layer 121. A material of the barrier metal layer 124 includes, for example, titanium nitride (TiN). Thus, a chemical element of the barrier metal layer 124 includes titanium and nitrogen (N). As the barrier metal layer 124, at least either the material contained in the barrier metal layer 124 or the material including the chemical element contained in the barrier metal layer 124 may be formed on the adhesion layer 121 by performing a CVD method. The barrier metal layer 124 may be formed on the inner walls of the contact hole 113 and the contact hole 143.

As described above, the adhesion intermediate film 120 including the adhesion layer 121 and the barrier metal layer 124 is formed on the insulating film 110. The adhesion intermediate film 120 may be formed on the inner walls of the contact hole 113 and the contact hole 143. The adhesion intermediate film 120 may be embedded in the contact hole 113 and the contact hole 143.

The metal film 130 is formed on the adhesion intermediate film 120. The metal film 130 may include a first metal layer 131, a second metal layer 132, and a third metal layer 133. The metal film 130 includes the first metal layer 131, the second metal layer 132, and the third metal layer 133 sequentially in a direction from the lower side toward the upper side. As described above, the metal film 130 includes the stacked film made of the mutually different stacked layers.

The first metal layer 131 is formed on the barrier metal layer 124 in the adhesion intermediate film 120. A material of the first metal layer 131 includes, for example, tungsten (W). Thus, a chemical element of the first metal layer 131 includes tungsten. As the first metal layer 131, at least either the material contained in the first metal layer 131 or the material including the chemical element contained the first metal layer 131 may be formed on the barrier metal layer 124 by performing a CVD method. The first metal layer 131 may be formed on the inner walls of the contact hole 113 and the contact hole 143.

The second metal layer 132 is formed on the first metal layer 131. A material of the second metal layer 132 may include, for example, titanium tungsten (TiW). Thus, a chemical element of the second metal layer 132 includes titanium and tungsten. As the second metal layer 132, at least either the material contained in the second metal layer 132 or the material including the chemical element of the second metal layer 132 may be formed on the first metal layer 131 by performing a PVD method. The second metal layer 132 may be formed on the inner walls of the contact hole 113 and the contact hole 143.

The third metal layer 133 is formed on the second metal layer 132. A material of the third metal layer 133 includes, for example, aluminum copper (AlCu). Thus, a chemical element of the third metal layer 133 includes aluminum (Al) and copper (Cu). As the third metal layer 133, at least either the material contained in the third metal layer 133 or the material including the chemical element contained in the third metal layer 133 may be formed on the second metal layer 132 by, for example, a sputtering method. The third metal layer 133 may be formed on the inner walls of the contact hole 113 and the contact hole 143.

As described above, the metal film 130 including the first metal layer 131, the second metal layer 132, and the third metal layer 133 is formed on the adhesion intermediate film 120. The metal film 130 may be formed on the inner walls of the contact hole 113 and the contact hole 143. The metal film 130 may be embedded in the contact hole 113 and the contact hole 143. The metal film 130 may be connected to the semiconductor layer of the semiconductor element formed on the semiconductor substrate 140 via the adhesion intermediate film 120.

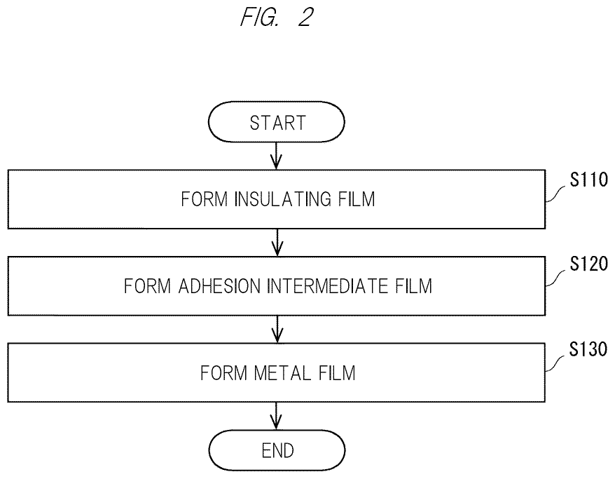

Next, a method of manufacturing the semiconductor device 101 according to the comparative example will be described. FIG. 2 is a flowchart illustrating the method of manufacturing the semiconductor device 101 according to the comparative example. As illustrated in FIG. 2, the method of manufacturing the semiconductor device 101 according to the comparative example includes step S110 of forming the insulating film 110, step S120 of forming the adhesion intermediate film 120, and step S130 of forming the metal film 130.

In step S110, the insulating film 110 is formed first. For example, the insulating film 110 containing silicon oxide is formed on the first main surface 141 of the semiconductor substrate 140.

Then, in step S120, the adhesion intermediate film 120 is formed on the insulating film 110. The adhesion intermediate film 120 includes, for example, the adhesion layer 121 containing titanium and the barrier metal layer 124 containing titanium nitride. Specifically, the adhesion layer 121 is formed on the insulating film 110 by a PVD method. Then, the barrier metal layer 124 is formed on the adhesion layer 121 by a CVD method.

Then, in step S130, the metal film 130 is formed on the adhesion intermediate film 120. The metal film 130 includes, for example, the first metal layer 131 containing tungsten arranged on the adhesion intermediate film 120, the second metal layer 132 containing titanium tungsten arranged on the first metal layer 131, and the third metal layer 133 containing aluminum copper arranged on the second metal layer 132. Specifically, the first metal layer 131 is formed on the barrier metal layer 124 by a CVD method. The second metal layer 132 is formed on the first metal layer 131 by a PVD method. Then, the third metal layer 133 is formed on the second metal layer 132 by a sputtering method.

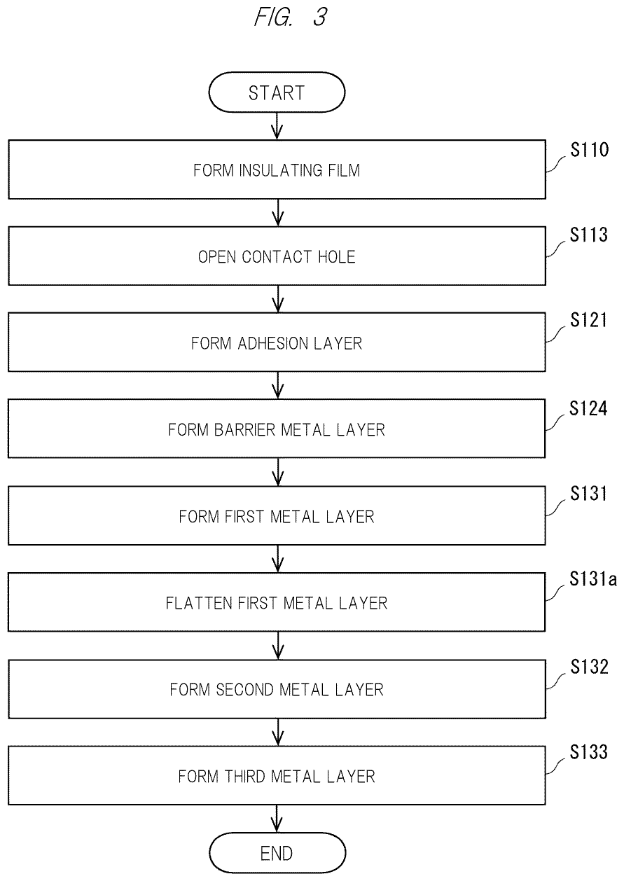

FIG. 3 is a flowchart illustrating another method of manufacturing the semiconductor device 101 according to the comparative example. As illustrated in FIG. 3, the another method of manufacturing the semiconductor device 101 includes step S110 of forming the insulating film 110, step S113 of opening the contact hole 113, step S121 of forming the adhesion layer 121, and step S124 of forming the barrier metal layer 124. The another method of manufacturing the semiconductor device 101 further includes step S131 of forming the first metal layer 131, step S131a of flattening the first metal layer 131, step S132 of forming the second metal layer 132, and step S133 of forming the third metal layer 133.

Step S110 is the same as above. Then, in step S113, the contact hole 113 is opened in the insulating film 110. Then, in step S121, the adhesion layer 121 [symbol] f the adhesion intermediate film 120 is formed on the insulating film 110 and on the inner wall of the contact hole 113 formed in the insulating film 110.

Specifically, the titanium-containing adhesion layer 121 is formed on the insulating film 110 and on the inner wall of the contact hole 113 formed in the insulating film 110 by a PVD method. Then, as illustrated in step S124, the barrier metal layer 124 containing titanium nitride is formed on the adhesion layer 121 and on the inner wall of the contact hole 113 by a CVD method.

Then, in step S131, the tungsten-containing first metal layer 131 is formed on the barrier metal layer 124 and on the inner wall of the contact hole 113 by a CVD method. Then, as illustrated in step S131a, an upper surface of the first metal layer 131 is flattened. For example, the upper surface of the first metal layer 131 is flattened by chemical mechanical polishing (CMP). Then, as illustrated in step S132, the titanium-tungsten-containing second metal layer 132 is formed on the first metal layer 131 by a PVD method. Then, as illustrated in step S133, the aluminum-copper-containing third metal layer 133 is formed on the second metal layer 132 by a sputtering method.

### Problems Found by Present Inventors

In the comparative example, the titanium-containing adhesion layer 121 is formed by, for example, a PVD method, when the adhesion intermediate film 120 including the adhesion layer 121 and the barrier metal layer 124 is formed on the insulting film 110 and on the inner wall of the contact hole 113 in the semiconductor device 101. The adhesion layer 121 formed by a PVD method may have high compression stress. Thus, if the metal film 130 is thick, the peeling of the adhesion layer 121 from the interface between the adhesion layer 121 and the insulating film 110 may be caused by stress or thermal stress of the metal film 130. Thereby, it is difficult to suppress the peeling of the metal film 130 formed on the insulating film 110.

An exemplary cause of the peeling of the adhesion layer 121 from the interface between the adhesion layer 121 and the insulating film 110 is physical bonding between the adhesion layer 121 formed by a PVD method and the insulating film 110.

### First Embodiment

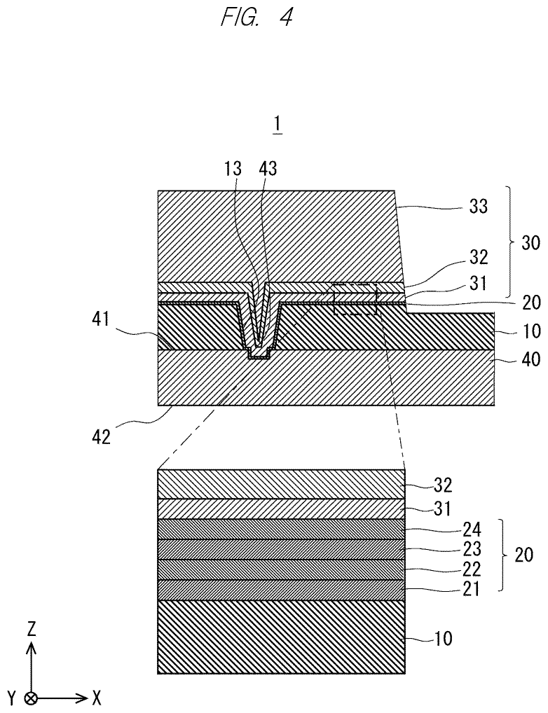

Next, a semiconductor device according to a first embodiment will be described. FIG. 4 is a cross-sectional view illustrating a semiconductor device 1 according to the first embodiment. FIG. 4 also illustrates an enlarged diagram of a part of the semiconductor device 1. As illustrated in FIG. 4, the semiconductor device 1 includes an insulating film 10, an adhesion intermediate film 20, a metal film 30, and a semiconductor substrate 40.

The semiconductor substrate 40 may have, for example, a plate shape. The plate shape of the semiconductor substrate 40 includes a first main surface 41 and a second main surface 42 opposite to the first main surface 41. A material of the semiconductor substrate 40 may include, for example, silicon as similar to the comparative example. However, other materials are not excluded as the material.

The formation of the semiconductor element including the semiconductor layer on the semiconductor substrate 40 is as the same as that of the comparative example. The semiconductor substrate 40 may include a contact hole 43 reaching the semiconductor layer of the semiconductor element. The semiconductor element may include the semiconductor layer such as IGBT, MOSFT, or diode.

The insulating film 10 is the same as the insulating film 110 according to the comparative example in the configuration and the function. A material of the insulating film 10 may include silicon oxide. Thus, a chemical element of the insulating film 10 may include silicon and oxygen. The insulating film 10 may include a contact hole 13 communicating with the contact hole 43. The adhesion intermediate film 20 is formed on the insulating film 10.

The adhesion intermediate film 20 is formed on the insulating film 10. The adhesion intermediate film 20 is arranged between the insulating film 10 and the metal film 30. The adhesion intermediate film 20 includes a first adhesion layer 21, a stress control layer 22, a second adhesion layer 23, and a barrier metal layer 24. The adhesion intermediate film 20 includes the first adhesion layer 21, the stress control layer 22, the second adhesion layer 23, and the barrier metal layer 24 which are mutually different and are arranged sequentially in a direction from the insulating film 10 toward the metal layer 30.

The first adhesion layer 21 is formed on the insulating film 10. A material of the first adhesion layer 21 includes, for example, TiSiO. Thus, a chemical element of the first adhesion layer 21 includes titanium. The first adhesion layer 21 contains titanium silicide. Note that the first adhesion layer 21 may contain other metal which makes silicide, instead of titanium. For example, the first adhesion layer 21 may contain at least any of cobalt (Co), nickel (Ni), molybdenum (Mo), hafnium (Hf), tantalum (Ta), tungsten, magnesium (Mg), chromium (Cr), manganese (Mn), iron (Fe), zirconium (Zr), niobium (Nb), rubidium (Rb), rhodium (Rh), palladium (Pd), rhenium (Re), iridium (Ir), and platinum (Pt). At least any of cobalt, nickel, molybdenum, hafnium, tantalum, tungsten, magnesium, chromium, manganese, iron, zirconium, niobium, rubidium, rhodium, palladium, rhenium, iridium, and platinum will be referred to as silicide metal below. Thus, the first adhesion layer 21 may contain silicide of a silicide metal. A chemical element of the first adhesion layer 21 further includes silicon and oxygen.

The first adhesion layer 21 is formed on the insulating film 10 by forming a halogenated metal film and then transforming it into a stacked transformation film as described later.

The stress control layer 22 is formed on the first adhesion layer 21. A material of the stress control layer 22 includes, for example, TiSiOClN. Thus, a chemical element of the stress control layer 22 includes titanium. Note that the stress control layer 22 may contain other metal instead of titanium. For example, the stress control layer 22 may contain a silicide metal. The stress control layer 22 may contain the same metal as the metal contained in the first adhesion layer 21.

The stress control layer 22 further contains chlorine. Note that the stress control layer 22 may contain other halogen instead of chlorine. That is, the stress control layer 22 may contain at least any of the halogens. The halogens include fluorine, chlorine, bromine, and iodine. A chemical element of the stress control layer 22 further includes silicon, oxygen, and nitrogen. The stress control layer 22 is formed on the first adhesion layer 21 by forming a halogenated metal film and then transforming it into a stacked transformation film as described later.

The second adhesion layer 23 is formed on the stress control layer 22. A material of the second adhesion layer 23 includes, for example, TiON. Thus, a chemical element of the second adhesion layer 23 includes titanium. Note that the second adhesion layer 23 may contain other metal instead of titanium. For example, the second adhesion layer 23 may contain a silicide metal. The second adhesion layer 23 may contain the same metal as those contained in the first adhesion layer 21 and the stress control layer 22.

A chemical element of the second adhesion layer 23 further includes oxygen and nitrogen. The second adhesion layer 23 is formed on the stress control layer 22 by forming a halogenated metal film and then transforming it into a stacked transformation film as described later.

The barrier metal layer 24 is formed on the second adhesion layer 23. A material of the barrier metal layer 24 includes titanium nitride. Thus, a chemical element of the barrier metal layer 24 includes titanium. Note that the barrier metal layer 24 may contain other metal instead of titanium. For example, the barrier metal layer 24 may contain a silicide metal. The barrier metal layer 24 may contain the same metal as at least any of the metals contained in the first adhesion layer 21, the stress control layer 22, and the second adhesion layer 23.

A chemical element of the barrier metal layer 24 further includes nitrogen. As the barrier metal layer 24, at least either the material contained in the barrier metal layer 24 or the material including the chemical element contained in the barrier metal layer 24 may be formed on the second adhesion layer 23 by performing a CVD method. The barrier metal layer 24 may be formed on the inner walls of the contact hole 13 and the contact hole 43.

As described above, the adhesion intermediate film 20 including the first adhesion layer 21, the stress control layer 22, the second adhesion layer 23, and the barrier metal layer 24 is formed on the insulating film 10. The first adhesion layer 21, the stress control layer 22, and the second adhesion layer 23 may contain the same metal as one another. For example, the same metal may be a silicide metal. Additionally, the barrier metal layer may also contain the same metal. The adhesion intermediate film 20 may be formed on the inner walls of the contact hole 13 and the contact hole 43. The adhesion intermediate film 20 may be embedded in the contact hole 13 and the contact hole 43.

The stress control layer 22 may be thinner than the first adhesion layer 21. The stress control layer 22 may be thinner than the second adhesion layer 23. The first adhesion layer 21, the stress control layer 22, and the second adhesion layer 23 may be thinner than the barrier metal layer 24. By such a configuration, the stress on the adhesion intermediate film 20 can be relaxed, and the adhesion can be improved.

The metal film 30 is formed on the adhesion intermediate film 20. The metal film 30 may include a first metal layer 31, a second metal layer 32, and a third metal layer 33. The metal layer 30 includes the first metal layer 31, the second metal layer 32, and the third metal layer 33 sequentially in a direction from the lower side toward the upper side. As described above, the metal film 30 includes a stacked film in which a plurality of different layers are stacked. The first metal layer 31, the second metal layer 32, and the third metal layer 33 in the metal film 30 are the same as the first metal layer 131, the second metal layer 132, and the third metal layer 133 in the metal film 130 according to the comparative example in the configuration and the function.

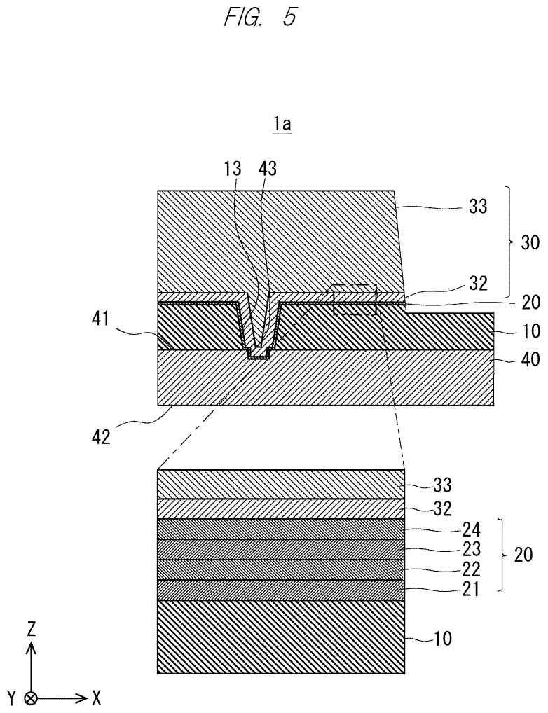

FIG. 5 is a cross-sectional view illustrating another semiconductor device 1a according to the first embodiment. Since the semiconductor device 1a includes the adhesion intermediate film 20 as illustrated in FIG. 5, the adhesion can be improved. Thus, the first metal layer 31 may be excluded. That is, the metal film 30 includes the second metal layer 32 and the third metal layer 33. The second metal layer 32 may be formed on the adhesion intermediate film 20 not via the first metal layer 31. Therefore, the metal film 30 includes the second metal layer 32 arranged on the adhesion intermediate film 20 and the third metal layer 33 arranged on the second metal layer 32. In the semiconductor device 1a, the first metal layer 31 can be excluded, and the step of manufacturing the first metal layer 31 can be omitted. Thereby, the manufacturing cost can be reduced.

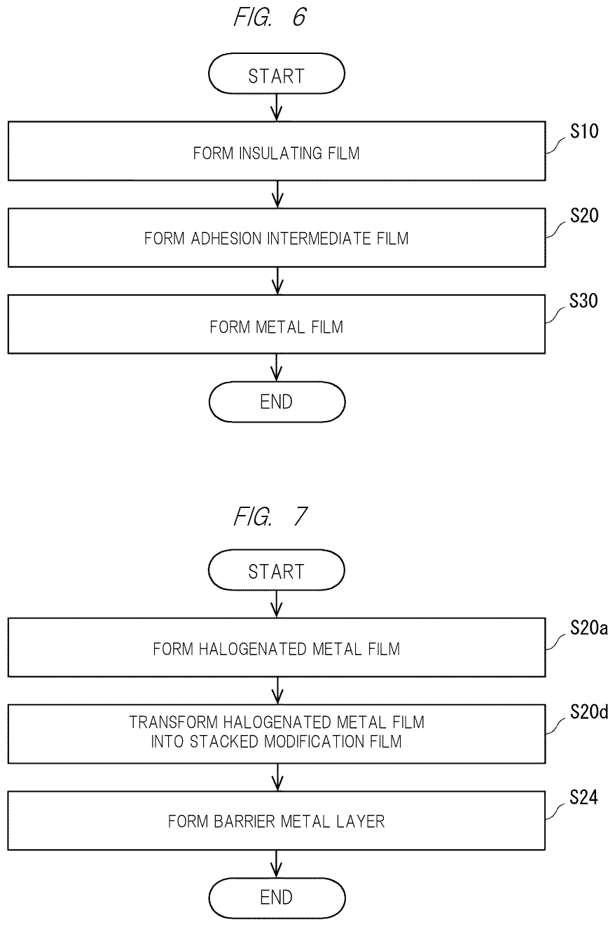

Next, a method of manufacturing the semiconductor device 1 will be described. FIG. 6 is a flowchart illustrating a method of manufacturing the semiconductor device 1 according to the first embodiment. As illustrated in FIG. 6, the method of manufacturing the semiconductor device 1 according to the first embodiment includes step S10 of forming the insulating film 10, step S20 of forming the adhesion intermediate film 20, and step S30 of forming the metal film 30.

In step S10, the insulating film 10 is formed first. For example, the insulating film 10 is formed on the first main surface 41 of the semiconductor substrate 40. The insulating film 10 may be formed on the semiconductor substrate 40 by, for example, thermal oxidization, a CVD method, or the like. The insulating film 10 may contain silicon oxide. Then, in step S20, the adhesion intermediate film 20 is formed on the insulating film 10.

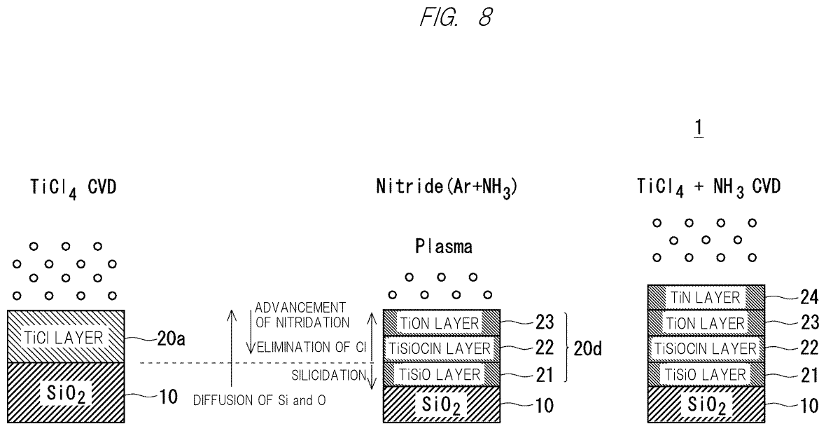

FIG. 7 is a flowchart illustrating the steps of manufacturing the adhesion intermediate film 20 in the method of manufacturing the semiconductor device 1 according to the first embodiment. FIG. 8 is a diagram illustrating the steps of manufacturing the adhesion intermediate film 20 in the method of manufacturing the semiconductor device 1 according to the first embodiment.

As illustrated in FIGS. 7 and 8, step S20 of forming the adhesion intermediate film 20 includes step S20a of forming a halogenated metal film 20a, step S20d of transforming the halogenated metal film 20a into a stacked transformation film 20d, and step S24 of forming the barrier metal layer 24.

In step S20a, the halogenated metal film 20a made by halogenating a metal is formed on the insulating film 10. A material of the halogenated metal film 20a includes, for example, titanium chloride (TiCl). Thus, a chemical element of the halogenated metal film 20a includes titanium and chlorine. Note that the halogenated metal film 20a may contain other metal instead of titanium. For example, the halogenated metal film 20a may contain a silicide metal. The halogenated metal film 20a may contain at least any of the halogens instead of chlorine.

In the present embodiment, the halogenated metal film 20a containing titanium chloride is formed immediately on the insulating film 10 by a CVD method using titanium tetrachloride (TiCl₄). The halogenated metal film 20a can be chemically bonded to the insulating film 10 by the formation under the CVD method. Thus, the adhesion of the halogenated metal film 20a can be further improved than that under a PVD method for physical bonding. Note that the formation of the halogenated metal film 20a on the insulating film 10 under the PVD method is not excluded from the present embodiment.

In step S20a, if the halogenated metal film 20a is too thick, the compression stress decreases, and the stress relaxation effect decreases. To the contrary, if the halogenated metal film 20a is too thin, the content of the halogen such as chlorine decreases, and thus, the stress relaxation effect decreases.

Then, in step S20d, the halogenated metal film 20a is transformed into the stacked transformation film 20d. The stacked transformation film 20d described here includes the first adhesion layer 21, the stress control layer 22, and the second adhesion layer 23 which are mutually different and are arranged sequentially in a direction from the insulating film 10. Thus, the adhesion intermediate film 20 includes the stacked transformation film 20d and the barrier metal layer 24.

In step S20d, the halogenated metal film 20a may be thermally processed under the ammonia-containing atmosphere to be transformed into the stacked transformation film 20d. For example, the halogenated metal film 20a is thermally processed and nitrided by thermal process under the atmosphere containing plasma-processed argon (Ar) and ammonia (NH₃). The halogenated metal film 20a may be thermally processed and nitrided by a CVD method generating plasma.

By the thermal process, silicon and oxygen are diffused from a region of the halogenated metal film 20, the region being close to the insulating film 10, into the halogenated metal film 20a. Thereby, silicon is diffused to, for example, the center of the halogenated metal film 20a. Oxygen is diffused to, for example, the upper surface of the halogenated metal film 20a.

The metal contained in the halogenated metal film 20a reacts with silicon and oxygen contained in the insulating film 10 to form silicide. Thereby, the first adhesion layer 21 containing the silicide of TiSiO or the like is formed on the upper side of the insulating film 10. As described above, the first adhesion layer 21 may contain the silicide. The first adhesion layer 21 may further contain silicon and oxygen.

To the contrary, by the nitridation process, the halogenated metal film 20a is nitride in a region from the upper surface of the halogenated metal film 20a. Thus, nitrogen is diffused to the center of the halogenated metal film 20a. Thereby, the TiSiOClN-containing stress control layer 22 is formed on the first adhesion layer 21. As described above, the stress control layer 22 may further contain at least any of the halogens. The stress control layer 22 may further contain silicon, oxygen, and nitrogen.

By the thermal process, halogen such as chlorine is eliminated from the halogenated metal film 20a. Halogen such as chlorine is eliminated from the top of the halogenated metal film 20a. Thereby, the second adhesion layer 23 containing TiON or the like is formed on the stress control layer 22. As described above, the second adhesion layer 23 may contain oxygen and nitrogen. Therefore, the stacked transformation film 20d is formed on the insulating film 10.

Then, as illustrated in step S24, the barrier metal layer 24 is formed on the stacked transformation film 20d. For example, the barrier metal layer 24 is formed on the stacked transformation film 20d by a CVD method using titanium tetrachloride and ammonia. The barrier metal layer 24 may contain a silicide metal. As described above, as illustrated in step S20, the adhesion intermediate film 20 is formed on the insulating film 10.

In step S20, the first adhesion layer 21, the stress control layer 22, and the second adhesion layer 23 may contain the same metal as one another. The same metal described here may include a silicide metal. The barrier metal layer 24 may also contain the same metal. In step S20, the stress control layer 22 may be made thinner than the first adhesion layer 21 and may be made thinner than the second adhesion layer 23. The first adhesion layer 21, the stress control layer 22, and the second adhesion layer 23 may be thinner than the barrier metal layer 24. In step S20, the adhesion intermediate film 20 may be formed on the inner wall of the contact hole 13 formed in the insulating film 10 and on the insulating film 10.

Then, as illustrated in step S30, the metal film 30 is formed on the adhesion intermediate film 20. The metal film 30 includes a stacked film in which a plurality of mutually different layers are stacked. For example, the metal film 30 includes the first metal layer 31, the second metal layer 32, and the third metal layer 33 as similar to the metal film 130 including the first metal layer 131, the second metal layer 132, and the third metal layer 133 according to the comparative example. In step S30, note that the metal film 30 may include the second metal layer 32 arranged on the adhesion intermediate film 20 and the third metal layer 33 arranged on the second metal layer 32 while the first metal layer 31 is excluded.

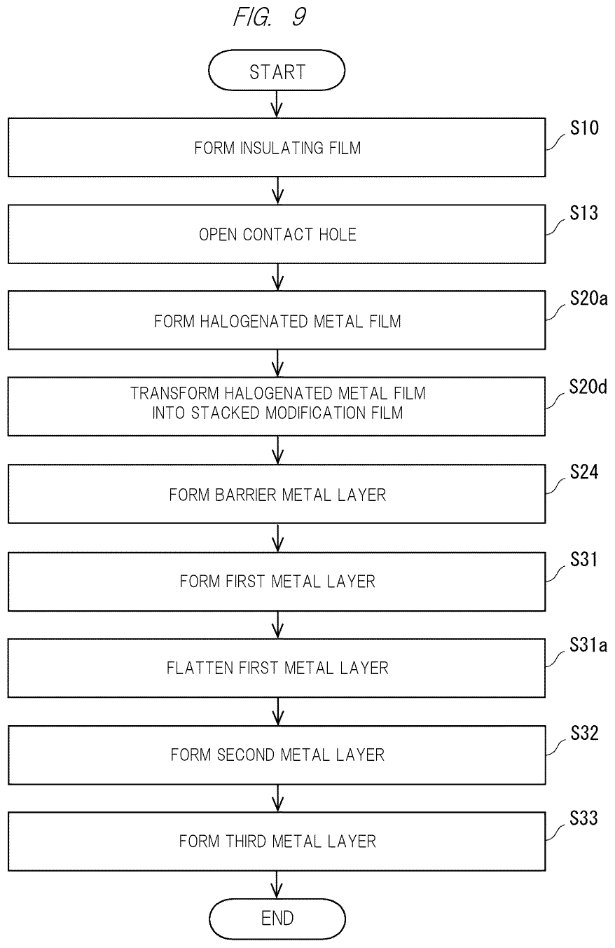

FIG. 9 is a flowchart illustrating a method of manufacturing the semiconductor device 1 according to another example of the first embodiment. As illustrated in FIG. 9, the method of manufacturing the semiconductor device 1 according to another example includes step S10 of forming the insulating film 10, step S13 of opening the contact hole 13, and step S20a of forming the halogenated metal film 20a. The method of manufacturing the semiconductor device 1 further includes step S20d of transforming the halogenated metal film 20a into the stacked transformation film 20d, step S24 of forming the barrier metal layer 24, step S31 of forming the first metal layer 31, step S31a of flattening the first metal layer 31, step S32 of forming the second metal layer 32, and step S33 of forming the third metal layer 33.

Step S10 and step S13 are the same as step S110 and step S113 in the comparative example, respectively. Step S31, step S31a, step S32, and step S33 are the same as step S131, step S131a, step S132, and step S133 in the comparative example, respectively. Step S20a, step S20d, and step S24 are as described above.

Next, the effects of the present embodiment will be described. In the semiconductor device 1 according to the present embodiment, the adhesion intermediate film 20 includes the first adhesion layer 21, the stress control layer 22, the second adhesion layer 23, and the barrier metal layer 24. Thereby, the adhesion between the insulating film 10 and the adhesion intermediate film 20 can be improved, and the peeling of the adhesion intermediate film 20 from the interface between the insulating film 10 and the adhesion intermediate film 20 can be prevented. Therefore, the peeling of the metal film 30 such as a wiring formed on the insulating film 10 can be prevented.

Specifically, on the insulating film 10, the semiconductor device 1 according to the present embodiment includes the stacked transformation film 20d including the first adhesion layer 21, the stress control layer 22, and the second adhesion layer 23, which are controlled in terms of composition. The stacked transformation film 20d is formed by transforming the halogenated metal film 20a into the first adhesion layer 21, the stress control layer 22, and the second adhesion layer 23 under use of segregation of halogen. First, the halogenated metal film 20a, which adheres immediately onto the insulating film 10, is formed by a CVD method. In the comparative example, the adhesion layer 121 which adheres immediately onto the insulating film 110 is formed by a PVD method. Thus, in the present embodiment, the method of forming the halogenated metal film 20a which adheres immediately onto the insulating film 10 is changed from the PVD method in the comparative example to the CVD method which is a higher-temperature film forming method. Therefore, the adhesion of the first adhesion layer 21 based on the halogenated metal film 20a adhering immediately onto the insulating film 10 can be improved. A reason why the adhesion of the first adhesion layer 21 can be improved by use of the high-temperature CVD method is that, for example, the adhesion layer 121 formed by the PVD method is physically bounded to the insulating film 110 while the first adhesion layer 21 based on the halogenated metal film 20a formed by the CVD method is chemically bonded to the insulating film 10.

In the present embodiment, thermal process conditions including an optimized ammonia plasma nitridation condition and the like are applied to a titanium layer containing chlorine impurity caused by titanium tetrachloride as a source gas. Thereby, a chlorine content of the halogenated metal film 20a is controlled, and the compression stress is adjusted in accordance with this content. Specifically, in the present embodiment, the first adhesion layer 21, the stress control layer 22, and the second adhesion layer 23 are selectively formed by use of the chlorine elimination reaction based on the film forming temperature and the ammonia plasma process condition. The chlorine elimination reaction can be expressed by the following reaction formula (1).

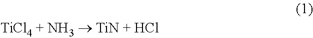

Therefore, by the control of the chlorine content of the halogenated metal film 20a, the compression stress can be adjusted in accordance with this content.

For example, the thin stress control layer 22 can decrease the compression stress. Thus, since the difference in stress between the insulating film 10 and the adhesion intermediate film 20 is small, the metal film 30 can endure the tensile stress during the formation. Thereby, the peeling of the metal film 30 can be suppressed, and the adhesion can be improved.

### First Modification Example

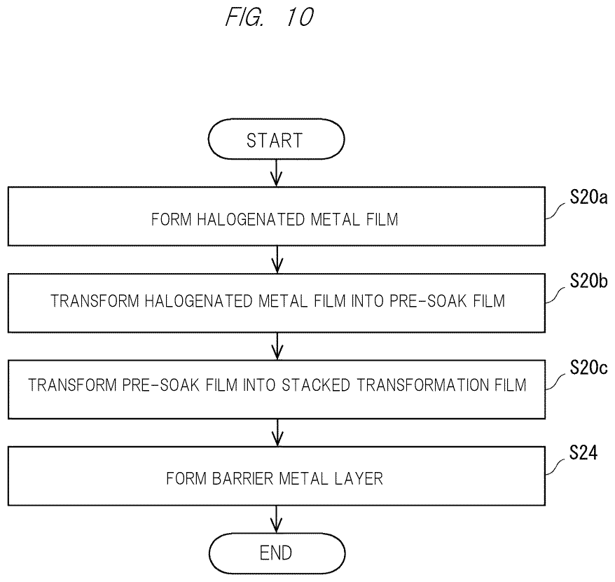

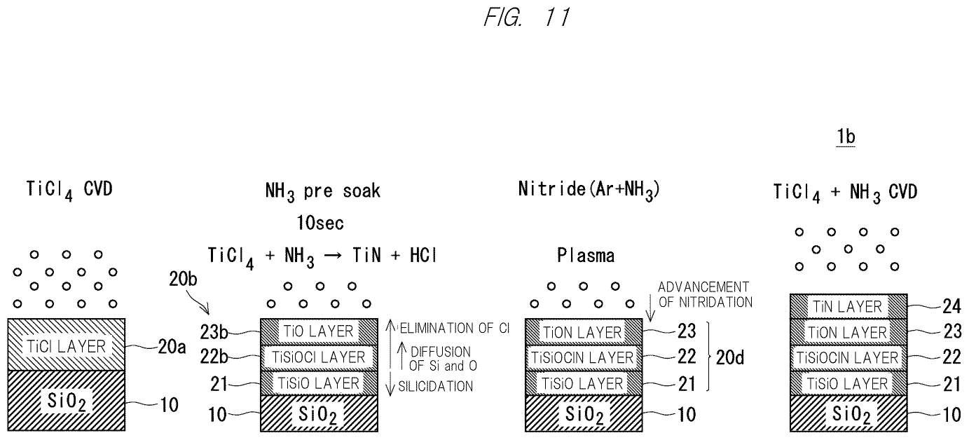

FIG. 10 is a flowchart illustrating the steps of manufacturing the adhesion intermediate film 20 in a method of manufacturing a semiconductor device 1b according to a first modification example of the first embodiment. FIG. 11 is a diagram illustrating the steps of manufacturing the adhesion intermediate film 20 in the method of manufacturing the semiconductor device 1b according to the first modification example of the first embodiment. As illustrated in FIGS. 10 and 11, the manufacturing method according to the present modification example includes step S20b of transforming the halogenated metal film 20a into a pre-soak film 20b after step of forming the halogenated metal film 20a. Then, step S20c of transforming the pre-soak film 20b into the stacked transformation film 20d is performed. That is, step S20d of transforming the halogenated metal film 20a into the stacked transformation film 20d includes step S20b of transforming the halogenated metal film 20a into the pre-soak film 20b and step S20c of transforming the pre-soak film 20b into the stacked transformation film 20d.

In step S20b, the halogenated metal film 20a is transformed into the pre-soak film 20b. For example, the halogenated metal film 20a is transformed into the pre-soak film 20b by a thermal process under the ammonia-containing atmosphere. In step S20b, the process other than nitrogen diffusion in step S20d is performed. That is, by the thermal process in step S20b, silicon and oxygen are diffused from a region of the halogenated metal film 20a, the region being close to the insulating film 10, into the halogenated metal film 20a. Thereby, silicon is diffused to, for example, the center of the halogenated metal film 20a. Oxygen is diffused to, for example, the upper surface of the halogenated metal film 20a.

The metal contained in the halogenated metal film 20a reacts with silicon and oxygen contained in the insulating film 10 to form silicide. Thereby, the first adhesion layer 21 containing the silicide made of TiSiO or the like is formed on the insulating film 10. As described above, the first adhesion layer 21 may contain the silicide. The first adhesion layer 21 may further contain silicon and oxygen.

A TiSiOCl-containing prestress control layer 22b is formed on the first adhesion layer 21 by a thermal process. As described above, the prestress control layer 22b may further contain at least any of the halogens. The stress control layer 22 may further contain silicon and oxygen.

By a thermal process, halogen such as chlorine is eliminated from the halogenated metal film 20a. Halogen such as chlorine is eliminated from the upper side of the halogenated metal film 20a. Thereby, a TiO-containing pre-second adhesion layer 23b is formed on the prestress control layer 22b. As described above, the pre-second adhesion layer 23b may contain oxygen and nitrogen. As described above, the first adhesion layer 21, the prestress control layer 22b, and the pre-second adhesion layer 23b, which are mutually different, are formed on the insulating film 10 sequentially in a direction from the insulating film 10.

In step S20c, the pre-soak film 20b is transformed into the stacked transformation film 20d. For example, the pre-soak film 20b is nitrided from the upper surface of the pre-soak film 20b by the nitridation process. Thus, nitrogen is diffused to the center of the pre-soak film 20b. Thereby, the TiSiOClN-containing stress control layer 22 is formed on the first adhesion layer 21. The TiON-containing second adhesion layer 23 is formed on the stress control layer 22. Therefore, the stacked transformation film 20d is formed on the insulating film 10.

The manufacturing method according to the present modification example includes step S20b of transforming the halogenated metal film 20a into the pre-soak film 20b and step S20c of transforming the pre-soak film 20b into the stacked transformation film 20d. In step S20b of transforming the halogenated metal film 20a into the pre-soak film 20b, advancement of the nitridation process can be prevented while advancement of the elimination of halogen such as chlorine is achieved. Thus, the formation of the halogen-containing prestress control layer 22b can be controlled. Thereby, the formation of the stress control layer 22 can be controlled.

### Second Modification Example

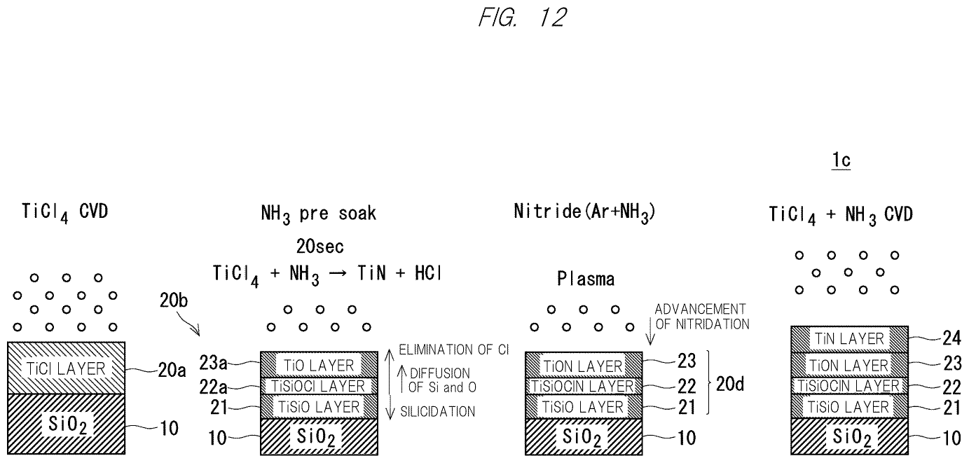

Next, a method of manufacturing a semiconductor device 1c according to a second modification example will be described. FIG. 12 is a diagram illustrating the steps of manufacturing the adhesion intermediate film 20 in the method of manufacturing the semiconductor device 1c according to the second modification example of the first embodiment. As illustrated in FIG. 12, in the method of manufacturing the semiconductor device 1c according to the present modification example, the process time in step S20b of transforming the halogenated metal film 20a into the pre-soak film 20b is changed. Thereby, the thickness of the prestress control layer 22b can be controlled. Thus, the thickness of the stress control layer 22 in the adhesion intermediate film 20 can be controlled. Specifically, the long process time in step S20b of transforming the halogenated metal film 20a into the pre-soak film 20b advances the elimination of halogen such as chlorine. Thereby, the thickness of the prestress control layer 22b is decreased. Thus, the thickness of the stress control layer 22 can be decreased in the subsequent step S20c of transforming the pre-soak film 20b into the stacked transformation film 20d. Therefore, the thickness of the stress control layer 22 can be controlled. The stress control layer 22 has a higher compression stress than those of the first adhesion layer 21 and the second adhesion layer 23, and therefore, can decrease the stress when being thinner than the second adhesion layer 23. The description for other configurations and effects is included in the descriptions for the first embodiment and the first modification example.

### Second Embodiment

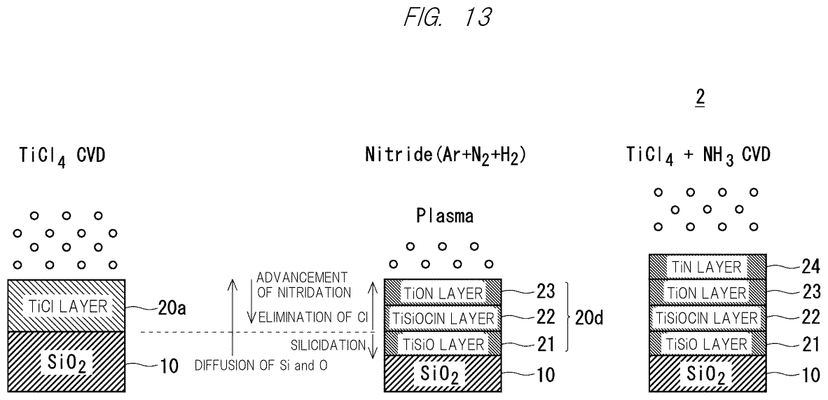

Next, a semiconductor device 2 according to a second embodiment will be described. In the semiconductor device 2 according to the present embodiment, gas used in the nitridation process is changed. FIG. 13 is a diagram illustrating the steps of manufacturing the adhesion intermediate film 20 in a method of manufacturing the semiconductor device 2 according to the second embodiment. As illustrated in FIG. 13, in the method of manufacturing the semiconductor device 2 according to the present embodiment, argon, nitrogen, and hydrogen are used instead of argon and ammonia for the thermal process and the nitridation process in step S20d of transforming the halogenated metal film 20a into the stacked transformation film 20d. The gas used for the processes in the present embodiment is changed from ammonia to nitrogen and hydrogen, thereby individually controlling the nitridation and the elimination of halogen. Specifically, the proportion of nitrogen in the gas used for the processes is increased, thereby advancing the nitridation. To the contrary, the proportion of hydrogen in the gas used for the processes is increased thereby advancing the elimination of halogen such as chlorine.

For example, the proportion of nitrogen is increased, thereby increasing the thicknesses of the second adhesion layer 23 and the stress control layer 22. To the contrary, the proportion of hydrogen is increased, thereby decreasing the thickness of the stress control layer 22. As described above, the proportions of nitrogen and hydrogen in the gas used for the processes are controlled, thereby controlling the thickness of each layer of the stacked transformation film 20d, and therefore, thereby controlling the compression stress on the adhesion intermediate film 20, and improving the adhesion of the metal film 30. The description for other configurations and effects is included in the descriptions for the first embodiment and each modification example.

### Third Embodiment

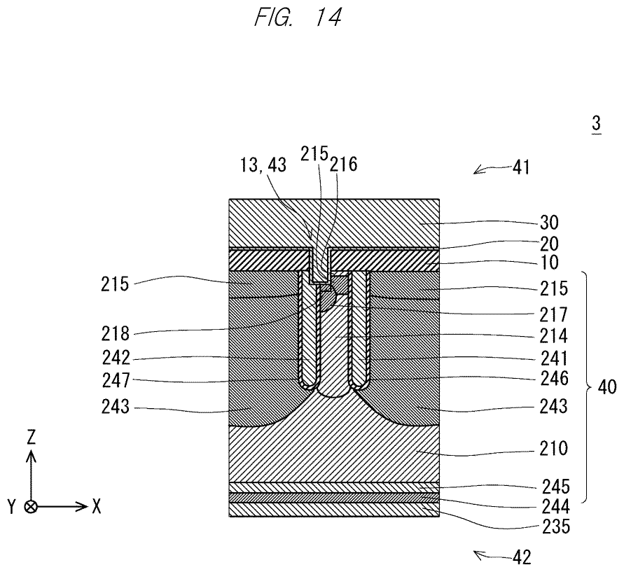

Next, a semiconductor device according to a third embodiment will be described. The present embodiment is an exemplary application to a semiconductor device including a specific semiconductor element such as IGBT. FIG. 14 is a cross-sectional view illustrating the semiconductor device 3 according to the third embodiment. As illustrated in FIG. 14, the semiconductor device 3 according to the present embodiment includes the semiconductor substrate 40, the insulating film 10, the adhesion intermediate film 20, the metal film 30 functioning as an emitter wiring, and a collector wiring 235. A plurality of semiconductor elements may be formed in the semiconductor device 3. The semiconductor elements include, for example, IGBT. Note that the semiconductor elements may include at least either one of MOSFET and diode. In the semiconductor substrate 40, components of the IGBT include an N− type drift layer 210, an N type barrier layer 214, a P type body layer 215, an N+ type emitter layer 216, a P+ type latch-up prevention layer 217, and a p+ type body contact layer 218. The semiconductor substrate 40 further includes a trench gate electrode 241, a trench emitter electrode 242, a P type floating layer 243, a P+ type collector layer 244, an N type field stop layer 245, a trench insulating film 246, and a trench insulating film 247. The metal film 30 functioning as an emitter wiring is connected to the N+ type emitter layer 216, the P type body layer 215, the P+ type body contact layer 218, and the trench emitter electrode 242 via the contact hole 13 and the contact hole 43. The collector wiring 235 is connected to the P+ type collector layer 244.

The N type barrier layer 214 is arranged closer to the +Z-axis direction side than the N− type drift layer 210. The N type barrier layer 214 extends in, for example, the Y-axis direction in plan view. The N type barrier layer 214 is sandwiched on the both sides between the trench gate electrode 241 and the trench emitter electrode 242 in the X-axis direction. That is, the N type barrier layer 214 is arranged in a region sandwiched between the trench gate electrode 241 and the trench emitter electrode 242.

The P type body layer 215 is arranged closer to the +Z-axis direction side than the N type barrier layer 214. The P type body layer 215 is sandwiched on both sides between the trench gate electrode 241 and the trench emitter electrode 242 in the X-axis direction. The P type body layer 215 is connected, via the adhesion intermediate film 20, to the metal film 30 filled in the contact hole 13 and the contact hole 43 penetrating the insulating film 10 and the N+ type emitter layer 216.

The N+ type emitter layer 216 is arranged closer to the +Z-axis direction side than the P type body layer 215. The N+ type emitter layer 216 is arranged in a region sandwiched between the trench gate electrode 241 and the trench emitter electrode 242. The N+ type emitter layer 216 is connected to the metal film 30 filled in the contact hole 13 and the contact hole 43 penetrating the insulating film 10.

The trench gate electrode 241 and the trench emitter electrode 242 are arranged to sandwich the N type barrier layer 214, the P type body layer 215, and the N+ type emitter layer 216 on both sides in the X-axis direction. The trench gate electrode 241 and the trench emitter electrode 242 have parts extending in, for example, the Y-axis direction in plan view. For example, the trench gate electrode 241 is arranged at the +X-axis direction side of the trench emitter electrode 242. The trench emitter electrode 242 is arranged at the −X-axis direction side of the trench gate electrode 241.

The trench gate electrode 241 is connected to, for example, a gate wiring. The trench emitter electrode 242 is connected, via the adhesion intermediate film 20 to the metal film 30 filled in the contact hole 13 and the contact hole 43 penetrating the insulating film 10. Thus, the N+ type emitter layer 216, the P type body layer 215, and the trench gate electrode 241 are connected to the metal film 30 functioning as the emitter wiring. A structure between the trench gate electrode 241 and the trench emitter electrode 242 is referred to as inter-trench structure. For example, the inter-trench structure of IGBT includes the N type barrier layer 214, the P type body layer 215, and the N+ type emitter layer 216. The inter-trench structure of IGBT may further include the P+ type latch-up prevention layer 217 and the P+ type body contact layer 218.

The P type floating layer 243 is arranged between adjacent IGBTs among a plurality of IGBTs. For example, the P type floating layer 243 is arranged between the trench gate electrode 241 of the IGBT at the −X-axis direction side and the trench emitter electrode 242 of the IGBT at the +X-axis direction side in the adjacent IGBTs. The P type floating layer 243 is opposite to the N type barrier layer 214, the P type body layer 215, and the N+ type emitter layer 216 across the trench gate electrode 241 or the trench emitter electrode 242.

The P type floating layer 243 is arranged closer to the +Z-axis direction side than the N− type drift layer 210. Thus, the P type floating layer 243, the trench emitter electrode 242 (covered with the trench insulating film 247), the inter-trench structure, the trench gate electrode 241 (covered with the trench insulating film 246), and the P type floating layer 243 are arranged at the +Z-axis direction side of the N− type drift layer 210 sequentially from the −X-axis direction side in the X-axis direction. The configuration is repeatedly arranged in the X-axis direction.

The trench insulating film 246 is arranged between the trench emitter electrode 242 and the semiconductor substrate 40. Specifically, the trench insulating film 246 is arranged between the trench emitter electrode 242 and the N− type drift layer 210, the N type barrier layer 214, the P type body layer 215, the N+ type emitter layer 216 and the P type floating layer 243. The trench insulating film 247 is arranged between the trench gate electrode 241 and the semiconductor substrate 40. Specifically, the trench insulating film 247 is arranged between the trench gate electrode 241 and the N− type drift layer 210, the N type barrier layer 214, the P type body layer 215, the N+ type emitter layer 216 and the P type floating layer 243.

The N type field stop layer 245 is arranged closer to the −Z-axis direction side than the N− type drift layer 210. The P+ type collector layer 244 is arranged closer to the −Z-axis direction side than the N type field stop layer 245. The P+ type collector layer 244 is connected to the collector wiring 235.

In the semiconductor device 3 according to the present embodiment, the insulating film 10 may be formed on the semiconductor substrate 40, and the adhesion intermediate film 20 may be formed on the insulating film 10 and on the inner walls of the contact hole 13 and the contact hole 43 formed in the insulating film 10. The metal film 30 is formed on the adhesion intermediate film 20. Specifically, for example, an IGBT including semiconductor layer including a drift layer, a channel layer, an emitter layer, and a collector layer may be formed in the semiconductor substrate 40. The insulating film 10 may be formed on the semiconductor substrate 40 having such a configuration. The adhesion intermediate film 20 may be formed on the insulating film 10 and on the inner walls of the contact hole 13 and the contact hole 43 penetrating from the upper surface of the insulating film 10 to the semiconductor layer in the semiconductor substrate 40. The metal film 30 is connected to the semiconductor layer via the adhesion intermediate film 20.

The method of manufacturing the semiconductor device 3 according to the present embodiment may further include a step of forming an IGBT including a semiconductor layer including a drift layer, a channel layer, an emitter layer, and a collector layer in the semiconductor substrate 40. In this case, in step S10, the insulating film 10 is formed on the semiconductor substrate 40 having such a configuration. In step S20, the adhesion intermediate film 20 is formed on the insulating film 10 and on the inner walls of the contact hole 13 and the contact hole 43 penetrating from the upper surface of the insulating film 10 to the semiconductor layer in the semiconductor substrate 40. In step S30, the metal film 30 is connected to the semiconductor layer via the adhesion intermediate film 20.

In the foregoing, the present disclosure has been concretely described based on the embodiments. However, it is needless to say that the present disclosure is not limited to the comparative example, the embodiments and the modification examples, and can be made within the scope of the present invention. For example, appropriate combinations of the configurations of the comparative example, the first to third embodiments, and the first and second modification examples are also within the scope of the technical idea of the embodiments. Further, the following configurations are also within the scope of the technical idea of the embodiments.

### Appendix A1

A semiconductor device includes: an insulating film; a metal film; and an adhesion intermediate film arranged between the insulating film and the metal film. The adhesion intermediate film includes: a first adhesion layer; a stress control layer; a second adhesion layer; and a barrier metal layer, which are mutually different and are arranged sequentially in a direction from the insulating film toward the metal film.

### Appendix A2

In the semiconductor device described in Appendix A1, the first adhesion layer, the stress control layer, and the second adhesion layer contain the same metal as one another. The same metal includes at least any of cobalt, nickel, molybdenum, hafnium, tantalum, tungsten, magnesium, chromium, manganese, iron, zirconium, niobium, rubidium, rhodium, palladium, rhenium, iridium, and platinum.

### Appendix A3

In the semiconductor device described in Appendix A2, the barrier metal layer contains the same metal.

### Appendix A4

In the semiconductor device described in Appendix A1, the barrier metal layer contains at least any of cobalt, nickel, molybdenum, hafnium, tantalum, tungsten, magnesium, chromium, manganese, iron, zirconium, niobium, rubidium, rhodium, palladium, rhenium, iridium, and platinum.

### Appendix A5

In the semiconductor device described in Appendix A1, a thickness of each of the first adhesion layer, the stress control layer, and the second adhesion layer is smaller than a thickness of the barrier metal layer.

### Appendix A6

The semiconductor device described in Appendix A1 further includes a semiconductor substrate. The insulating film is formed on the semiconductor substrate, the adhesion intermediate film is formed on the insulating film and on an inner wall of a contact hole formed in the insulating film, and the metal film is formed on the adhesion intermediate film.

### Appendix B1

A method of manufacturing a semiconductor device includes: a step of forming an insulating film; a step of forming an adhesion intermediate film on the insulating film; and a step of forming a metal film on the adhesion intermediate film. In the step of forming the adhesion intermediate film, the adhesion intermediate film including a first adhesion layer, a stress control layer, a second adhesion layer, and a barrier metal layer, which are mutually different and are arranged sequentially in a direction from the insulating film toward the metal film, is formed.

### Appendix B2

In the method of manufacturing the semiconductor device described in Appendix B1, in the step of forming the insulating film, the insulating film contains silicon oxide.

### Appendix B3

In the method of manufacturing the semiconductor device described in Appendix B1, in the step of forming the metal film, the metal film includes a stacked film in which a plurality of mutually different layers are stacked.

### Appendix B4

In the method of manufacturing the semiconductor device described in Appendix B1, in the step of forming the metal film, the metal film includes: a first metal layer containing tungsten arranged on the adhesion intermediate film; a second metal layer containing titanium arranged on the first metal layer; and a third metal layer containing aluminum arranged on the second metal layer.

### Appendix B5

In the method of manufacturing the semiconductor device described in Appendix B1, in the step of forming the metal film, the metal film includes: a second metal layer containing titanium arranged on the adhesion intermediate film; and a third metal layer containing aluminum arranged on the second metal layer.

### Appendix B6

In the method of manufacturing the semiconductor device described in Appendix B1, in the step of forming the adhesion intermediate film, the first adhesion layer, the stress control layer, and the second adhesion layer contain the same metal as one another. The same metal includes at least any of cobalt, nickel, molybdenum, hafnium, tantalum, tungsten, magnesium, chromium, manganese, iron, zirconium, niobium, rubidium, rhodium, palladium, rhenium, iridium, and platinum.

### Appendix B7

In the method of manufacturing the semiconductor device described in Appendix B6, in the step of forming the adhesion intermediate film, the first adhesion layer contains silicide.

### Appendix B8

In the method of manufacturing the semiconductor device described in Appendix B6, in the step of forming the adhesion intermediate film, the first adhesion layer further contains silicon and oxygen.

### Appendix B9

In the method of manufacturing the semiconductor device described in Appendix B6, in the step of forming the adhesion intermediate film, the stress control layer further contains at least any of halogens.

### Appendix B10

In the method of manufacturing the semiconductor device described in Appendix B6, in the step of forming the adhesion intermediate film, the stress control layer further contains silicon, oxygen, and nitrogen.

### Appendix B11

In the method of manufacturing the semiconductor device described in Appendix B6, in the step of forming the adhesion intermediate film, the second adhesion layer further contains oxygen and nitrogen.

### Appendix B12

In the method of manufacturing the semiconductor device described in Appendix B6, in the step of forming the adhesion intermediate film, the barrier metal layer contains the same metal.

### Appendix B13

In the method of manufacturing the semiconductor device described in Appendix B1, in the step of forming the adhesion intermediate film, the barrier metal layer contains at least any of cobalt, nickel, molybdenum, hafnium, tantalum, tungsten, magnesium, chromium, manganese, iron, zirconium, niobium, rubidium, rhodium, palladium, rhenium, iridium, and platinum.

### Appendix B14

In the method of manufacturing the semiconductor device described in Appendix B1, in the step of forming the adhesion intermediate film, a thickness of the stress control layer is smaller than a thickness of the first adhesion layer.

### Appendix B15

In the method of manufacturing the semiconductor device described in Appendix B1, in the step of forming the adhesion intermediate film, a thickness of the stress control layer is smaller than a thickness of the second adhesion layer.

### Appendix B16

In the method of manufacturing the semiconductor device described in Appendix B1, in the step of forming the adhesion intermediate film, a thickness of each of the first adhesion layer, the stress control layer, and the second adhesion layer is smaller than a thickness of the barrier metal layer.

### Appendix B17

In the method of manufacturing the semiconductor device described in Appendix B1, the insulating film in the step of forming the insulating film is formed on a semiconductor substrate, the adhesion intermediate film in the step of forming the adhesion intermediate film is formed on the insulating film and on an inner wall of a contact hole formed in the insulating film, and the metal film in the step of forming the metal film is formed on the adhesion intermediate film.

### Appendix B18

In the method of manufacturing the semiconductor device described in Appendix B1, the step of forming the adhesion intermediate film includes: a step of forming, on the insulating film, a halogenated metal film formed by halogenating a metal; a step of transforming the halogenated metal film into a stacked transformation film including the first adhesion layer, the stress control layer, and the second adhesion layer, which are mutually different and are arranged sequentially in a direction from the insulating film; and a step of forming the barrier metal layer on the stacked transformation film.

### Appendix B19

In the method of manufacturing the semiconductor device described in Appendix B18, in the step of transforming the halogenated metal film into the stacked transformation film, the halogenated metal film is transformed into the stacked transformation film by a CVD method generating plasma.

### Appendix B20

In the method of manufacturing the semiconductor device described in Appendix B18, in the step of forming the halogenated metal film, the halogenated metal film is formed on the insulating film by a CVD method.

What is claimed is:

1. A semiconductor device comprising:
an insulating film;
a metal film; and
an adhesion intermediate film arranged between the insulating film and the metal film,
wherein the adhesion intermediate film includes:
a first adhesion layer;
a stress control layer;
a second adhesion layer; and
a barrier metal layer, and
wherein the first adhesion layer, the stress control layer, the second adhesion layer and the barrier metal layer are mutually different and are arranged sequentially in a direction from the insulating film toward the metal film.

2. The semiconductor device according to claim 1,
wherein the insulating film contains silicon oxide.

3. The semiconductor device according to claim 1,
wherein the metal film includes a stacked film in which a plurality of mutually different layers are stacked.

4. The semiconductor device according to claim 1,
wherein the metal film includes:
a first metal layer containing tungsten arranged on the adhesion intermediate film;
a second metal layer containing titanium arranged on the first metal layer; and
a third metal layer containing aluminum arranged on the second metal layer.

5. The semiconductor device according to claim 1,
wherein the metal film includes:
a second metal layer containing titanium arranged on the adhesion intermediate film; and
a third metal layer containing aluminum arranged on the second metal layer.

6. The semiconductor device according to claim 1,
wherein the first adhesion layer, the stress control layer, and the second adhesion layer contain the same metal as one another, and
wherein the same metal includes at least any of cobalt, nickel, molybdenum, hafnium, tantalum, tungsten, magnesium, chromium, manganese, iron, zirconium, niobium, rubidium, rhodium, palladium, rhenium, iridium, and platinum.

7. The semiconductor device according to claim 6,
wherein the first adhesion layer contains silicide.

8. The semiconductor device according to claim 6,
wherein the first adhesion layer further contains silicon and oxygen.

9. The semiconductor device according to claim 6,
wherein the stress control layer further contains at least any of halogens.

10. The semiconductor device according to claim 6,
wherein the stress control layer further contains silicon, oxygen, and nitrogen.

11. The semiconductor device according to claim 6,
wherein the second adhesion layer further contains oxygen and nitrogen.

12. The semiconductor device according to claim 1,
wherein a thickness of the stress control layer is smaller than a thickness of the first adhesion layer.

13. The semiconductor device according to claim 1,
wherein a thickness of the stress control layer is smaller than a thickness of the second adhesion layer.

14. The semiconductor device according to claim 1, further comprising:
a semiconductor substrate in which an IGBT is formed, the IGBT including a semiconductor layer including a drift layer, a channel layer, an emitter layer, and a collector layer,
wherein the insulating film is formed on the semiconductor substrate,
wherein the adhesion intermediate film is formed on the insulating film and on an inner wall of a contact hole penetrating from an upper surface of the insulating film to the semiconductor layer in the semiconductor substrate, and
wherein the metal film is connected to the semiconductor layer via the adhesion intermediate film.

15. A method of manufacturing a semiconductor device, the method comprising:
forming an insulating film;
forming an adhesion intermediate film on the insulating film; and
forming a metal film on the adhesion intermediate film,
wherein in forming the adhesion intermediate film, the adhesion intermediate film includes a first adhesion layer, a stress control layer, a second adhesion layer, and a barrier metal layer, and
wherein the first adhesion layer, the stress control layer, the second adhesion layer, and the barrier metal layer are mutually different and are arranged sequentially in a direction from the insulating film toward the metal film.

16. The method according to claim 15,
wherein forming the adhesion intermediate film includes:
forming, on the insulating film, a halogenated metal film formed by halogenating a metal;
transforming the halogenated metal film into a stacked transformation film including the first adhesion layer, the stress control layer, and the second adhesion layer, wherein the first adhesion layer, the stress control layer, and the second adhesion layer are mutually different and are arranged sequentially in a direction from the insulating film; and
forming the barrier metal layer on the stacked transformation film.

17. The method according to claim 16,
wherein transforming the halogenated metal film into the stacked transformation film includes:
transforming the halogenated metal film into a pre-soak film including a first adhesion layer, a pre-stress control layer, and a pre-second adhesion layer, wherein the first adhesion layer, the pre-stress control layer, and the pre-second adhesion layer are mutually different and are arranged sequentially in a direction from the insulating film; and
transforming the pre-soak film into the stacked transformation film including the first adhesion layer, the stress control layer, and the second adhesion layer, wherein the first adhesion layer, the stress control layer, and the second adhesion layer are mutually different and are arranged sequentially in a direction from the insulating film.

18. The method according to claim 16,
wherein in transforming the halogenated metal film into the stacked transformation film, the halogenated metal film is transformed into the stacked transformation film by thermal process under an atmosphere containing ammonia.

19. The method according to claim 16,
wherein in transforming the halogenated metal film into the stacked transformation film, the halogenated metal film is transformed into the stacked transformation film by thermal process under an atmosphere containing nitrogen and hydrogen.

20. The method according to claim 15, comprising:
forming, in a semiconductor substrate, an IGBT including a semiconductor layer including a drift layer, a channel layer, an emitter layer, and a collector layer,
wherein in forming the insulating film, the insulating film is formed on the semiconductor substrate,
wherein in forming the adhesion intermediate film, the adhesion intermediate film is formed on the insulating film and on an inner wall of a contact hole penetrating from an upper surface of the insulating film toward the semiconductor layer in the semiconductor substrate, and
wherein in forming the metal film, the metal film is connected to the semiconductor layer via the adhesion intermediate film.
